(19) United States
(12) Patent Application Publication
(10) Pub. No.: US 2025/0331327 A1
(43) Pub. Date: Oct. 23, 2025

(54) IMAGE SENSOR

(71) Applicant: Samsung Electronics Co., Ltd., Suwon-si (KR)

(72) Inventors: Seung Jae LEE, Suwon-si (KR); Duk Seo PARK, Suwon-si (KR); Jin Pyo KIM, Suwon-si (KR); Jae Sang YOO, Suwon-si (KR); Yong Suk CHOI, Suwon-si (KR); Ha Kyu CHOI, Suwon-si (KR)

(21) Appl. No.: 19/028,152

(22) Filed: Jan. 17, 2025

(30) Foreign Application Priority Data
Apr. 17, 2024 (KR) 10-2024-0051639

(51) Int. Cl. H10F 39/00

(52) U.S. Cl. CPC H10F 39/807; H10F 39/8057; H10F 39/809; H10F 39/811

(57) ABSTRACT

An image sensor including a first and second substrate, a first trench disposed on an active pixel area in the first substrate, a first wiring structure disposed on a first surface of the first substrate, the first wiring structure includes a first wiring pattern and a first bonding pad electrically connected to the first wiring pattern, and a second wiring structure disposed on the second substrate and including a second wiring pattern electrically connected to a pad and a second bonding pad. The first and second bonding pads are in contact with each other, at least a portion of the pad connects to a pad opening, the first trench electrically connects to the pad via the first wiring pattern, the first bonding pad, the second bonding pad, and the second wiring pattern. The active pixel area comprises a light receiving area, a light-blocking area, and an area disposed between.

### CROSS-REFERENCE TO RELATED APPLICATION

This application claims priority to Korean Patent Application No. 10-2024-0051639 filed on Apr. 17, 2024 in the Korean Intellectual Property Office, and all the benefits accruing therefrom under 35 U.S.C. 119, the content of which in its entirety is herein incorporated by reference.

### BACKGROUND

### Field

The present disclosure relates to an image sensor.

### Description of Related Art

An image sensor is a semiconductor device that converts optical information into an electrical signal. The image sensor may include a CCD (Charge Coupled Device) image sensor and a CMOS (Complementary Metal-Oxide Semiconductor) type image sensor.

The image sensor may be constructed in a form of a package, where the package may be structured to protect the image sensor and at the same time may be constructed such that light is incident on a light-receiving surface photo or a sensing area of the image sensor.

### SUMMARY

A technical purpose that the present disclosure aims to achieve is to provide an image sensor in which a patterning process defect may be prevented.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

According to an example embodiment of the present disclosure, an image sensor includes a first substrate including a first surface and a second surface opposite to each other; a first trench disposed on an active pixel area in the first substrate; a first wiring structure disposed on the first surface of the first substrate, the first wiring structure includes a first wiring pattern and a first bonding pad electrically connected to the first wiring pattern; a second substrate; and a second wiring structure disposed on the second substrate, the second wiring structure includes a second wiring pattern, a pad, and a second bonding pad electrically connected to the pad and the second wiring pattern, wherein the first bonding pad is in contact with the second bonding pad, wherein at least a portion of the pad is configured to connect to a pad opening extending through the first substrate, wherein the first trench is configured to electrically connect to the pad via the first wiring pattern, the first bonding pad, the second bonding pad, and the second wiring pattern, and wherein the active pixel area comprises a light receiving area, a light-blocking area, and an area disposed between the light-blocking area and a pad area.

According to an example embodiment of the present disclosure, an image sensor includes a first substrate including a first surface and a second surface opposite to each other; a first wiring structure on the first surface of the first substrate, the first wiring structure comprises a first bonding pad; a first trench in the first substrate and in contact with the first surface of the first substrate; a second substrate; and a second wiring structure disposed on the second substrate, the second wiring structure comprises a second bonding pad and a pad, wherein the pad is configured to electrically connect to the first trench through the second bonding pad and the first bonding pad, and wherein at least a portion of the pad is connected to a pad opening extending through the first substrate.

According to an example embodiment of the present disclosure, an image sensor includes a first substrate including a first surface and a second surface opposite to each other; a first wiring structure on the first surface of the first substrate, the first wiring structure comprises a first bonding pad; a first trench in the first substrate in contact with the first surface of the first substrate and the second surface of the first substrate; a second substrate; and a second wiring structure disposed on the second substrate, the second wiring structure comprises a second bonding pad and a pad, wherein the pad is configured to electrically connect to the first trench through the second bonding pad and the first bonding pad, wherein at least a portion of the pad connected to a pad opening extending via the first substrate, and wherein the first trench comprises a filling pattern, an insulating pattern disposed between the filling pattern and the first substrate, and a capping pattern disposed in the first substrate and in contact with the filling pattern.

Specific details of other embodiments are included in detailed descriptions and drawings.

### BRIEF DESCRIPTION OF DRAWINGS

The above and other aspects and features of the present disclosure will become more apparent by describing in detail illustrative embodiments thereof with reference to the attached drawings, in which:

FIG. 1 is an example block diagram for illustrating an image sensor according to some embodiments;

FIG. 2 is an example circuit diagram for illustrating an image sensor according to some embodiments;

FIG. 3 is an example layout diagram for illustrating an image sensor according to some embodiments;

FIG. 4 is a schematic cross-sectional view for illustrating an image sensor according to some embodiments;

FIG. 5 to FIG. 7 are various enlarged views for illustrating a R1 area in FIG. 4;

FIG. 8 and FIG. 9 are various schematic cross-sectional views for illustrating an image sensor according to some embodiments;

FIG. 10 is a schematic cross-sectional view for illustrating an image sensor according to some embodiments;

FIG. 11 is a schematic cross-sectional view for illustrating an image sensor according to some embodiments;

FIG. 12 and FIG. 13 are various enlarged views of a R2 area in FIG. 11;

FIGS. 14 to 16 are various schematic cross-sectional views for illustrating an image sensor according to some embodiments;

FIG. 17 is an example layout diagram for illustrating an image sensor according to some embodiments;

FIGS. 18 to 20 are diagrams of intermediate structures corresponding to intermediate steps of a method for manufacturing an image sensor according to some embodiments; and

FIGS. 21 to 25 are diagrams of intermediate structures corresponding to intermediate steps of a method for manufacturing an image sensor according to some embodiments.

### DETAILED DESCRIPTIONS

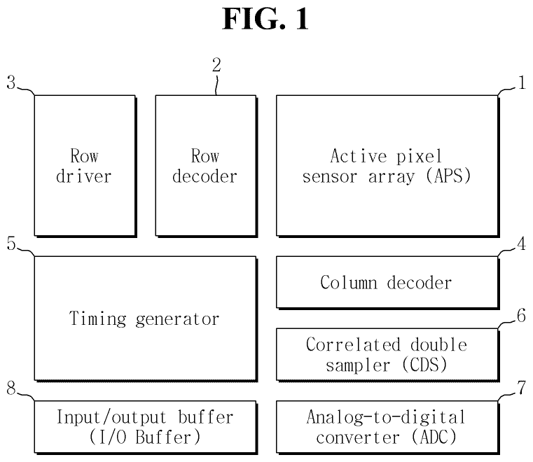

FIG. 1 is an example block diagram for illustrating an image sensor according to some embodiments.

Referring to FIG. 1, the image sensor according to some embodiments may include an active pixel sensor array (APS) 1, a row decoder 2, a row driver 3, a column decoder 4, a timing generator 5, a correlated double sampler (CDS) 6, an analog-to-digital converter (ADC) 7, and an input/output buffer (I/O Buffer) 8.

The active pixel sensor array 1 may include a plurality of unit pixels arranged two-dimensionally and may convert an optical signal into an electrical signal. The active pixel sensor array 1 may operate based on a plurality of driving signals such as a pixel select signal, a reset signal, and a charge transfer signal from the row driver 3. Furthermore, an electrical signal generated from the active pixel sensor array 1 may be provided to the correlated double sampler 6.

The row driver 3 may provide the plurality of driving signals for driving the plurality of unit pixels to the active pixel sensor array 1 according to a decoding result from the row decoder 2. When the unit pixels are arranged in a matrix form, the driving signals may be provided on each row basis.

The timing generator 5 may provide a timing signal and a control signal to the row decoder 2 and the column decoder 4.

The correlated double sampler (CDS) 6 may receive the electrical signal generated from the active pixel sensor array 1 and perform hold and sampling on the received electrical signal. The correlated double sampler 6 may double-sample a specific noise level and a signal level resulting from the electrical signal and output a difference level corresponding to a difference between the noise level and the signal level.

The analog to digital converter (ADC) 7 may convert an analog signal corresponding to the difference level output from correlated double sampler 6 into a digital signal and output the digital signal.

The input/output buffer 8 may latch the digital signal, and may sequentially output the latched digital signal to an image signal processor (not shown) according to a decoding result from the column decoder 4.

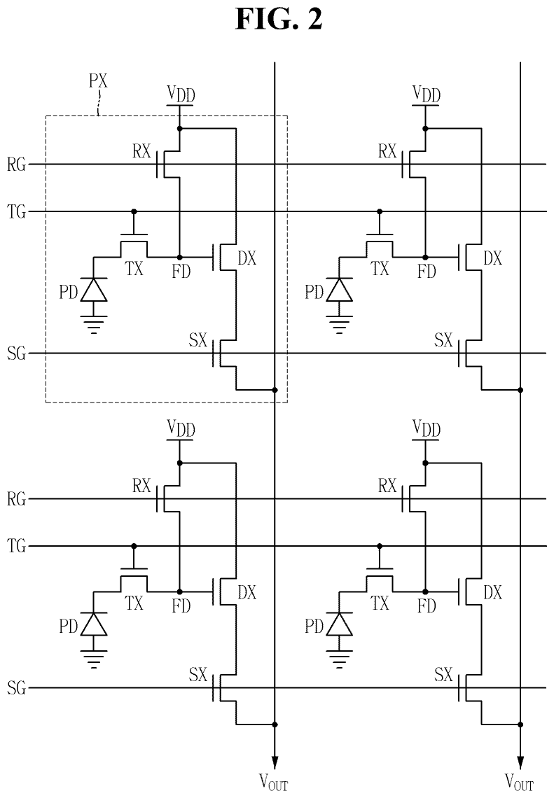

FIG. 2 is an illustrative circuit diagram for illustrating an image sensor according to some embodiments.

Referring to FIG. 2, an image sensor according to some embodiments may include a plurality of unit pixels PX.

The plurality of unit pixels PX may be arranged two-dimensionally (for example, in a matrix form). Each unit pixel PX may include a photoelectric conversion area PD, a transfer transistor TX, a floating diffusion area FD, a reset transistor RX, a drive transistor DX and a select transistor SX.

The photoelectric conversion area PD may generate charges in proportion to an amount of light incident from an outside. The photoelectric conversion area PD may be coupled with the transfer transistor TX which transfers the generated and accumulated charges to the floating diffusion area FD. The floating diffusion area FD is an area that converts the charges into voltage. Because the floating diffusion area FD has parasitic capacitance, charges may be stored therein in an accumulated manner. The photoelectric conversion area PD may include a photo diode, a photo transistor, a photo gate, a pinned photo diode, or a combination thereof.

One end of the transfer transistor TX may be connected to the photoelectric conversion area PD, and the other end of the transfer transistor TX may be connected to the floating diffusion area FD. The transfer transistor TX may be embodied as a transistor operating based on a predetermined bias (for example, a transfer signal TG). In other words, the transfer transistor TX may transfer the charge generated from the photoelectric conversion area PD to the floating diffusion area FD based on the transfer signal TG.

The drive transistor DX may be embodied as a source follower buffer amplifier. The drive transistor DX may amplify a change in an electrical potential of the floating diffusion area FD having received the charges from the photoelectric conversion area PD and output the amplified change to an output line V_{OUT}. When the drive transistor DX is turned on, a predetermined electrical potential provided to a drain of the drive transistor DX, for example, a power voltage V_{DD} may be transferred to a drain area of the select transistor SX.

The select transistor SX may select the unit pixel PX to be read on a row basis. The select transistor SX may be embodied as a transistor operating based on a predetermined bias (for example, a row select signal SG) applied from a select line.

The reset transistor RX may periodically reset the floating diffusion area FD. The reset transistor RX may be embodied as a transistor operating based on a predetermined bias (for example, a reset signal RG) applied from a reset line. When the reset transistor RX is turned on based on the reset signal RG, the predetermined electrical potential provided to a drain of the reset transistor RX, for example, the power supply V_{DD} may be transferred to the floating diffusion area FD, so that the floating diffusion area FD may be reset.

In FIG. 2, each unit pixel PX is shown as having one photoelectric conversion area PD and four transistors TX, RX, DX, and SX. However, this is only an example. In another example, at least one of the reset transistor RX, the drive transistor DX, and the select transistor SX may be shared with neighboring unit pixels PX.

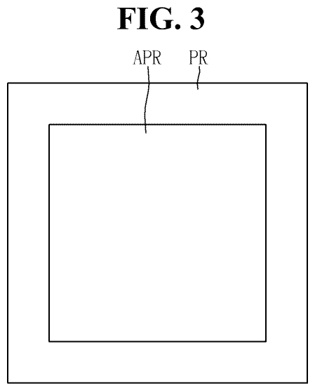

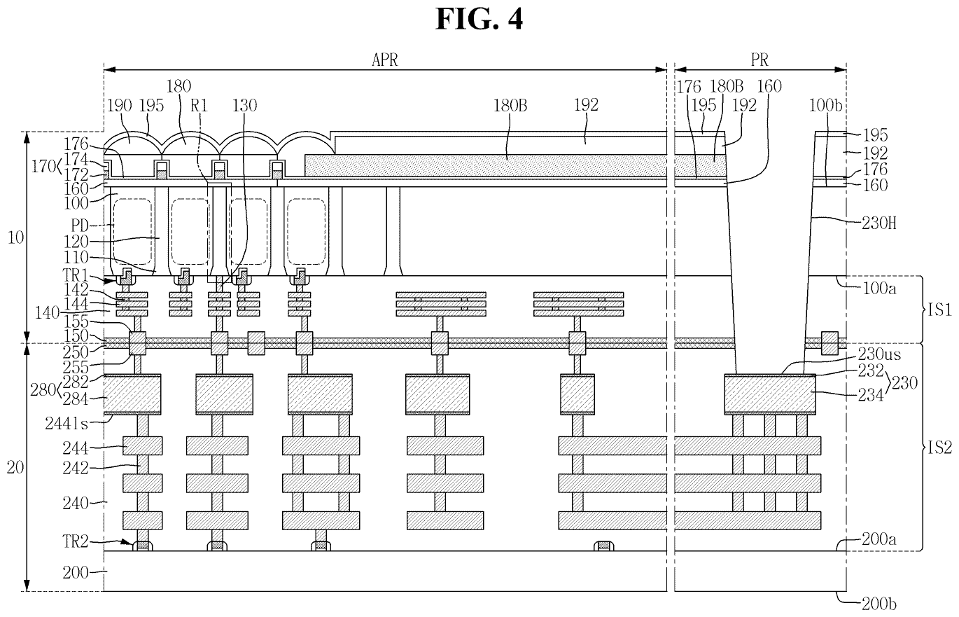

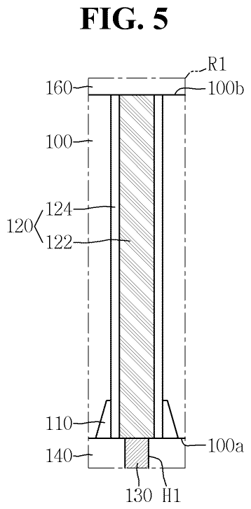

FIG. 3 is an example layout diagram for illustrating an image sensor according to some embodiments. FIG. 4 is a schematic cross-sectional view for illustrating an image sensor according to some embodiments. FIG. 5 to FIG. 7 are various enlarged views for illustrating a R1 area in FIG. 4.

Referring to FIG. 3, the image sensor according to some embodiments may include an active pixel area APR and a pad area PR.

The active pixel area APR may be disposed in an inner area of the image sensor. The active pixel area APR may include an area corresponding to the active pixel sensor array 1 in FIG. 1. For example, a plurality of unit pixels (for example, PX in FIG. 2, hereinafter referred to as PX) may be formed in the active pixel area APR, and may be arranged two-dimensionally (for example, in a matrix form).

For example, the active pixel area APR may include a light receiving area where active pixels that receive light and generate an active signal based on the received light are arranged, and a light-blocking area where optical black pixels which block light to generate an optical black signal are arranged. For example, the light-blocking area may surround the light receiving area in a plan view. However, this is only an example.

The pad area PR may be disposed on at least one side of the active pixel area APR. The pad area PR may be formed around the active pixel area APR. For example, the pad area PR may be disposed on four sides of the active pixel area APR in a plan view. For example, the pad area PR may surround the active pixel area APR.

The pad area PR may be configured to transmit and receive an electrical signal of the active pixel area APR. The pad area PR may be connected to an external device, etc. and configured to transmit and receive the electrical signal between the image sensor and the external device. In FIG. 3, the arrangement of the active pixel area APR and the pad area PR is an example and may vary.

Referring to FIG. 3 and FIG. 4, the image sensor according to some embodiments includes a first structure 10 and a second structure 20 sequentially stacked. The image sensor may be a stack type image sensor including a stack structure in which the first structure 10 and the second structure 20 are sequentially stacked.

The first structure 10 may include a first substrate 100, a photoelectric conversion area PD, an element isolation pattern 110, a pixel isolation pattern 120, a first circuit element TR1, a first wiring structure IS1, a surface insulating film 160, a grid pattern 170, a first protective film 176, a color filter 180, a light-blocking pattern 180B, a micro lens 190, a planarization film 192, and a second protective film 195.

The first substrate 100 may be a semiconductor substrate. For example, the first substrate 100 may be made of bulk silicon or SOI (silicon-on-insulator). The first substrate 100 may be a silicon substrate, or may include a material other than silicon, such as silicon germanium, indium antimonide, lead telluride compound, indium arsenide, indium phosphide, gallium arsenide, or gallium antimonide. Alternatively, the first substrate 100 may include a base substrate and an epitaxial layer formed on the base substrate. For convenience of description, in following embodiments, an example in which the first substrate 100 is embodied as a silicon substrate is set forth.

The first substrate 100 may include a first surface 100a and a second surface 100b, which are opposite to each other. In the following embodiments, the first surface 100a may be referred to as a front surface of the first substrate 100, and the second surface 100b may also be referred to as a back surface of the first substrate 100. In some embodiments, the second surface 100b of the first substrate 100 may be a light-receiving surface on which light is incident. That is, the image sensor according to some embodiments may be a backside illumination (BSI) type image sensor.

A plurality of unit pixels PX may be arranged in the first substrate 100 of the active pixel area APR. For example, in the first substrate 100 of the active pixel area APR, the active pixels that receive light and generate the active signal based on the light, and the optical black pixels that generate an optical black signal by blocking light may be arranged. Additional dummy pixels may be formed in a first portion of the substrate 100 of the active pixel area APR.

In some embodiments, the first substrate 100 may have a first conductivity type. The first conductivity type may be, for example, p-type. For example, the first substrate 100 may contain p-type impurities such as boron (B), aluminum (Al), indium (In), or gallium (Ga). However, this is only an example. In another example, the first conductivity type may be n-type.

The photoelectric conversion area PD may be formed within the first substrate 100 of the active pixel area APR. The photoelectric conversion area PD may be formed within each of the unit pixels PX arranged within the first substrate 100 of the active pixel area APR. For example, a plurality of photoelectric conversion areas PD may be arranged two-dimensionally (for example, in a matrix form) within the first substrate 100 of the active pixel area APR.

The photoelectric conversion area PD may have a second conductivity type that is different from the first conductivity type.

For example, the photoelectric conversion area PD may be formed within a portion of the active pixel area APR, and may not be formed within a portion of the active pixel area APR adjacent to the pad area PR.

The element isolation pattern 110 may be formed within the first substrate 100. For example, the element isolation pattern 110 may contact the first surface 100a of the first substrate 100 and be spaced apart from the second surface 100b. The element isolation pattern 110 may be formed within the first substrate 100 so as to define an active area within each unit pixel PX. The active area may include a floating diffusion area (FD of FIG. 2), and the floating diffusion area may have the second conductivity type that is different from the first conductivity type.

The element isolation pattern 110 may be formed by embedding an insulating material in a shallow trench formed in the first surface 100a toward the second surface 100b. The element isolation pattern 110 may include at least one of an insulating material, for example, silicon oxide, silicon nitride, silicon oxynitride, and a combination thereof. However, embodiments of the present disclosure are not limited thereto. Throughout the specification, when a component is described as “including” or “include” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

The pixel isolation pattern 120 may be formed within the first substrate 100. For example, the pixel isolation pattern 120 may extend through the first substrate 100. For example, the pixel isolation pattern 120 may be formed within a trench extending through the first substrate 100. The pixel isolation pattern 120 may fill the trench.

The pixel isolation pattern 120 may define each of a plurality of unit pixels PX within the first substrate 100. For example, the pixel isolation pattern 120 may be formed in a grid manner and within the first substrate 100 so as to surround each of the photoelectric conversion areas PD arranged in a matrix manner. The pixel isolation pattern 120 may separate the photoelectric conversion areas PD. The pixel isolation pattern 120 may be between the photoelectric conversion areas PD adjacent each other. The pixel isolation pattern 120 may improve light collection efficiency by refracting or reflecting light incident at an angle to the photoelectric conversion area PD. Furthermore, the pixel isolation pattern 120 may prevent photocharges generated in a specific unit pixel from migrating to other unit pixels adjacent thereto due to random drift.

The first circuit element TR1 may be formed on the first surface 100a of the first substrate 100. The first circuit element TR1 may include various transistors for processing an electrical signal generated from each of the unit pixels PX within the first substrate 100. For example, the first circuit element TR1 may include the transfer transistor TX, the reset transistor RX, the drive transistor DX, or the select transistor SX as described above with reference to FIG. 2.

In some embodiments, the first circuit element TR1 may include a vertical transfer transistor. For example, the first circuit element TR1 including the transfer transistor TX as described above with reference to FIG. 2 may have a portion thereof extending in the first substrate 100. This vertical transfer transistor may contribute to high integration of the image sensor by reducing an area size of the unit pixel.

The first wiring structure IS1 may be formed on the first surface 100a of the first substrate 100. The first wiring structure IS1 may include a first inter-wiring insulating film 140 on the first surface 100a, a first wiring pattern 130, 142, and 144 within the first inter-wiring insulating film 140, a first bonding insulating film 150 within the first inter-wiring insulating film 140, and a first bonding pad 155 within the first bonding insulating film 150 and/or the first inter-wiring insulating film 140.

In some embodiments, the first wiring pattern 130, 142, and 144 may include a contact 130, a plurality of first vias 142, and a plurality of first wiring lines 144.

The contact 130 may be formed within the first inter-wiring insulating film 140 of the active pixel area APR. The contact 130 may be formed as the lowermost metal layer of the first wiring structure IS1. The contact 130 may be connected to the pixel isolation pattern 120. The contact 130 may be disposed at various locations within the first inter-wiring insulating film 140 of the active pixel area APR and may be connected to the pixel isolation pattern 120.

The plurality of first vias 142 may connect the contact 130 and the plurality of first wiring lines 144 to each other. The plurality of first vias 142 may connect the plurality of first wiring lines 144 to each other. The plurality of first vias 142 may connect the plurality of first wiring lines 144 and the first bonding pad 155 to each other. The plurality of first vias 142 may connect the plurality of first wiring lines 144 and the first circuit element TR1 to each other. The contact 130 may be electrically connected to the first bonding pad 155 via the first wiring pattern 142 and 144.

In FIG. 4, the arrangement and number of contacts 130, the number of layers and arrangement of the plurality of first wiring lines 144, the number of layers and arrangement of the plurality of first vias 142, and the arrangement and number of the first bonding pads 155 are merely examples and may vary. The number of the pixel isolation pattern 120 connected to the contact 130 may be two or more. The first inter-wiring insulating film 140 may be formed in a stack structure in which a plurality of insulating layers are stacked.

For example, the first wiring insulating film 140 may include silicon oxide, and the first bonding insulating film 150 may include silicon oxide, silicon nitride, silicon oxynitride, or silicon carbon nitride. For example, each of the first wiring pattern 142 and 144 and the contact 130 may include at least one of copper (Cu), aluminum (Al), tungsten (W), titanium (Ti), titanium nitride (TiN), tantalum (Ta), tantalum nitride (TaN), ruthenium (Ru), and tungsten nitride (WN).

The first wiring structure IS1 may be electrically connected to the first circuit element TR1 and may transmit and receive the electrical signal to and from each unit pixel of the active pixel area APR.

The surface insulating film 160 may be formed on the second surface 100b of the first substrate 100. The surface insulating film 160 may conformally extend along the second surface 100b of the first substrate 100. The surface insulating film 160 may include, but is not limited to, at least one of an insulating material, for example, silicon oxide, silicon nitride, silicon oxynitride, aluminum oxide, hafnium oxide, and combinations thereof.

The surface insulating film 160 may be provided as an anti-reflection film and may prevent reflection of light incident on the second surface 100b as the light-receiving surface. Thus, the light reception of the photoelectric conversion area PD may be improved. Alternatively, the surface insulating film 160 may be provided as a planarization film, thereby allowing the color filter 180 and the micro lens 190 to be formed so as to have a uniform height.

In some embodiments, the surface insulating film 160 may be formed as a multi-film. For example, unlike what is shown, the surface insulating film 160 may include an aluminum oxide film, a hafnium oxide film, a silicon oxide film, a silicon nitride film, and a hafnium oxide film which are sequentially stacked on the second surface 100b of the first substrate 100.

The grid pattern 170 may be formed on the surface insulating film 160 of the active pixel area APR. The grid pattern 170 may surround each unit pixel PX while being disposed on the first substrate 100. For example, the grid pattern 170 may be formed in a grid manner and on the surface insulating film 160 and may surround each of the unit pixels PX arranged in a matrix manner.

In some embodiments, the grid pattern 170 may include a first film 172 and a second film 174. The first film 172 and the second film 174 may be sequentially stacked on the surface insulating film 160.

The first film 172 may include metal material, for example. The first film 172 may include, but is limited to, at least one of, for example, titanium (Ti), titanium nitride (TiN), tantalum (Ta), tantalum nitride (TaN), tungsten (W), aluminum (Al), copper (Cu), and combinations thereof. The first film 172 may prevent charges generated due to ESD (electrostatic discharge) from accumulating on the surface (for example, the second surface 100b) of the first substrate 100, thereby effectively preventing ESD bruise defects.

The second film 174 may include a low refractive index material with a lower refractive index than that of silicon (Si). For example, the second film 174 may include at least one of silicon oxide, aluminum oxide, tantalum oxide, and combinations thereof. However, embodiments of the present disclosure are not limited thereto. The second film 174 may improve light collection efficiency by refracting or reflecting light incident obliquely on the second surface 100b of the active pixel area APR.

The first protective film 176 may be formed on the surface insulating film 160 and the grid pattern 170. The first protective film 176 may extend conformally along a profile of the surface insulating film 160 and the grid pattern 170. The first protective film 176 may prevent damage to the surface insulating film 160 and the grid pattern 170. The first protective film 176 may include, for example, aluminum oxide (AlO). However, embodiments of the present disclosure are not limited thereto.

The color filter 180 may be formed on the first protective film 176 of the active pixel area APR. The color filter 180 may be positioned to correspond to each unit pixel PX. For example, a plurality of color filters 180 may be arranged two-dimensionally (for example, in a matrix form) so as to correspond to the plurality of photoelectric conversion areas PD, respectively. The grid pattern 170 may be formed in a grid manner and may surround each of the color filters 180 arranged in a matrix manner.

The color filter 180 may have various colors depending on a color of the unit pixels. For example, the color filter 180 may include a red color filter, a green color filter, a blue color filter, a yellow color filter, a magenta color filter, and a cyan color filter, and a white color filter.

The light-blocking pattern 180B may be formed on a portion of the surface insulating film 160 of the active pixel area APR. The light-blocking pattern 180B may cover at least a portion of the surface insulating film 160 of the active pixel area APR. In some embodiments, although not illustrated, a first protective film may extend further along an upper surface of the light-blocking pattern 180B. In some embodiments, the light-blocking pattern 180B may be formed on a portion of the surface insulating film 160 of the pad area PR to cover the surface insulating film 160 of the pad area PR. The light-blocking pattern 180B may block light incident on the first substrate 100. In the following embodiments, an area at which the photoelectric conversion area may be referred to as a light receiving area, and an area at which the light-blocking pattern 180B may be referred to as a light-blocking area.

The micro lens 190 may be formed on the color filter 180. The micro lens 190 may be positioned to correspond to each of the unit pixels (for example, PX in FIG. 2). For example, a plurality of micro lenses 190 may be arranged two-dimensionally (for example, in a matrix form) so as to correspond to the plurality of photoelectric conversion areas 101, respectively.

The micro lens 190 may have a convex shape and may have a predetermined radius of curvature. Accordingly, the micro lens 190 may converge light incident on the photoelectric conversion area PD. The micro lens 190 may include, for example, a light-transmissive resin. However, embodiments of the present disclosure are not limited thereto.

The planarization film 192 may be formed on the light-blocking pattern 180B. The planarization film 192 may cover a portion of the active pixel area APR and the pad area PR. In some embodiments, the planarization film 192 may be formed at the same vertical level as that of the micro lens 190. As used herein, “being formed at the same vertical level” means being formed in the same manufacturing process. For example, the planarization film 192 may include the light-transmissive resin included in the micro lens 190.

A second protective film 195 may be formed on the micro lens 190. The second protective film 195 may extend along a surface of the micro lens 190. The second protective film 195 may be formed on the planarizing film 192. The second protective film 195 may include an inorganic oxide film such as a silicon oxide film, a titanium oxide film, a zirconium oxide film, or a hafnium oxide film. However, embodiments of the present disclosure are not limited thereto. For example, the second protective film 195 may include a low temperature oxide (LTO).

The second protective film 195 may protect the micro lens 190 from the outside. For example, the second protective film 195 may include an inorganic oxide film to protect the micro lens 190 including an organic material. Furthermore, the second protective film 195 may improve the quality of the image sensor by improving the light-gathering efficiency of the micro lens 190. For example, the second protective film 195 may fill a space between adjacent ones of the micro lenses 190 to reduce reflection, refraction, scattering, etc. of incident light reaching the space between the micro lenses 190. The second protective film 195 may protect the planarization film 192 from the outside.

The first structure 10 may be stacked on the second structure 20. The second structure 20 may include a second substrate 200, a second circuit element TR2, and a second wiring structure IS2.

The second substrate 200 may be made of bulk silicon or SOI (silicon-on-insulator). The second substrate 200 may be a silicon substrate, or may include a material other than silicon, such as silicon germanium, indium antimonide, lead telluride compound, indium arsenide, indium phosphide, gallium arsenide, or gallium antimonide. Alternatively, the second substrate 200 may have a base substrate and an epitaxial layer formed on the base substrate. For convenience of description, in following embodiments, an example in which the second substrate 200 is embodied as a silicon substrate is described.

The second substrate 200 may include a third surface 200a and a fourth surface 200b that are opposite to each other. In the following embodiments, the third surface 200a may be referred to as a front surface of the second substrate 200, and the fourth surface 200b may be referred to as a back surface of the second substrate 200. In some embodiments, the third surface 200a of the second substrate 200 may face the first surface 100a of the first substrate 100.

The second circuit element TR2 may be formed on the third surface 200a of the second substrate 200. The second circuit element TR2 may be electrically connected to the active pixel area APR and may transmit and receive the electrical signal to and from each unit pixel PX. For example, the second circuit element TR2 may include circuit elements that constitute the row decoder 2, the row driver 3, the column decoder 4, the timing generator 5, the correlated double sampler 6, the analog-to-digital converter 7, or the input/output buffer 8 as described above with reference to FIG. 1.

The second wiring structure IS2 may be formed on the third surface 200a of the second substrate 200. The second wiring structure IS2 may include a second front side inter-wiring insulating film 240 on the third surface 200a, a second wiring pattern 242, 244, and 280 and a pad 230 within the second front side inter-wiring insulating film 240, a second bonding insulating film 250 on the second front side inter-wiring insulating film 240, and a second bonding pad 255 within the second bonding insulating film 250 and/or the second front side inter-wiring insulating film 240. The second wiring pattern 242, 244, and 280 may include a plurality of second wiring lines 244 and 280 and a plurality of second vias 242 connecting the plurality of second wiring lines 244 and 280 to each other. The plurality of second vias 242 may connect the second bonding pad 255 and the plurality of second wiring lines 244 and 280 to each other. The plurality of second vias 242 may connect the second circuit element TR2 and the plurality of second wiring lines 244 and 280 to each other. The second wiring structure IS2 may be electrically connected to the second circuit element TR2.

In FIG. 4, the number and arrangement of the second wiring patterns 242, 244, and 280 and the position of the second bonding pad 255 are merely examples, and may vary. The second front side inter-wiring insulating film 240 may be formed in a stack structure in which a plurality of insulating layers are stacked.

For example, the second front side inter-wiring insulating film 240 may include silicon oxide, and the second bonding insulating film 250 may include silicon oxide, silicon nitride, silicon oxynitride, or silicon carbon nitride. For example, the second wiring pattern 242, 244, and 280 may include at least one of copper (Cu), aluminum (Al), tungsten (W), titanium (Ti), titanium nitride (TiN), tantalum (Ta), tantalum nitride (TaN), ruthenium (Ru), and tungsten nitride (WN).

The pad 230 may be disposed within the second structure 20 of the pad area PR. The pad 230 may be disposed within the second wiring structure IS2 of the pad area PR. A pad opening 230H may extend through the first structure 10 of the pad area PR. At least a portion of the pad 230 may be exposed through the pad opening 230H. At least a portion of the upper surface 230us of the pad 230 may be exposed through the pad opening 230H. A lower surface and a side surface of the pad 230 may be surrounded with the second wiring structure IS2, and an upper surface 230us of the pad 230 may be exposed through the pad opening 230H.

In some embodiments, the pad 230 may be disposed within the second front side inter-wiring insulating film 240 of the pad area PR. A vertical level of the upper surface 230us of the pad 230 may be higher than a vertical level of a lower surface 244ls of the second wiring line 280 which is closest to the second bonding pad 255 among the second wiring lines 244 and 280. For example, the pad 230 may be formed in the same metal layer as that of the second wiring line 280 which is closest to the second bonding pad 255 among the second wiring lines 244 and 280.

For example, a sidewall of the pad 230 may extend substantially in a perpendicular manner to the substrate. In another example, a width of the pad 230 may increase or decrease as the pad extends in a direction from the second wiring structure IS2 toward the second substrate 200.

A plurality of second vias 242 may connect the pad 230 and the plurality of second wiring lines 242 and 280 to each other. The pad 230 may be electrically connected to the second wiring pattern 242, 244, and 280 and the second bonding pad 255.

For example, the pad 230 may include at least one of aluminum (Al), gold (Au), nickel (Ni), copper (Cu), tungsten (W), and titanium nitride (TiN).

In some embodiments, the pad 230 may include a barrier layer 232 and a pad layer 234. The barrier layer 232 may be formed on an upper surface and/or a lower surface of the pad layer 234. For example, the pad layer 234 may include aluminum (Al), and the barrier layer 232 may include titanium (Ti). In some embodiments, the barrier layer 232 may be omitted.

In some embodiments, the second wiring pattern 280 formed in the same metal layer as that of the pad 230 may be formed at the same vertical level as that of the pad 230. The second wiring pattern 280 may have the same structure as that of the pad 230. For example, the second wiring pattern 280 may include a wiring layer 284 and a barrier layer 282 formed on an upper surface and/or a lower surface of the wiring layer 284. The wiring layer 284 may include the same material as that of the pad layer 234, and the barrier layer 282 may include the same material as that of the barrier layer 232.

In some embodiments, the second wiring pattern 280 formed in the same metal layer as that of the pad 230 may be formed at a different vertical level than that of the pad 230 (may be formed in a different manufacturing process from a process in which the pad 230 is formed). The second wiring layer 284 may include the same material as that of the second wiring pattern 242 and 244. The second wiring pattern 280 may be omitted, and the second wiring pattern 242 and 244 may be formed at a location where the second wiring pattern 280 has been omitted and may be connected to the second bonding pad 255.

The first structure 10 and the second structure 20 may be bonded to each other. The first wiring structure IS1 and the second wiring structure IS2 may be bonded to each other. For example, as shown in FIG. 4, a lower surface of the first wiring structure IS1 may be attached to an upper surface of the second wiring structure IS2. The first wiring structure IS1 and the second wiring structure IS2 may be bonded to each other in, for example, a wafer bonding process. However, embodiments of the present disclosure are not limited thereto.

The first bonding pad 155 formed as the uppermost metal layer of the first wiring structure IS1 and the second bonding pad 255 formed as the uppermost metal layer of the second wiring structure IS2 may contact each other and be attached to each other. For example, each of the first bonding pad 155 and the second bonding pad 255 may be made of copper (Cu), and the first bonding pad 155 and the second bonding pad 255 may be bonded to each other in a Cu—Cu bonding manner. Alternatively, each of the first bonding pad 155 and the second bonding pad 255 may be made of various other metals such as aluminum (Al) or tungsten (W). The first bonding pad 155 and the second bonding pad 255 may be bonded to each other such that the first wiring structure IS1 and the second wiring structure IS2 may be electrically connected to each other.

The first bonding insulating film 150 and the second bonding insulating film 250 may also be in contact with each other and attached to each other. For example, the first wiring structure IS1 and the second wiring structure IS2 may be stacked in a metal-oxide hybrid bonding manner.

The pixel isolation pattern 120 may be electrically connected to the pad 230 via the first wiring structure IS1 and the second wiring structure IS2, and may receive a ground voltage or negative voltage from the pad 230.

In some embodiments, the pixel isolation pattern 120 may be electrically connected to the pad 230 via the contact 130, the first wiring pattern 142, 144, the first bonding pad 155, the second bonding pad 255, and the second wiring pattern 242, 244, and 280.

Referring to FIG. 5 to FIG. 7, the pixel isolation pattern 120 may include a filling pattern 122 and an insulating pattern 124.

The pixel isolation pattern 120 may extend through the first substrate 100 and the element isolation pattern 110. For example, the filling pattern 122 may include a conductive material. For example, the filling pattern 122 may include at least one of polysilicon (poly Si), metal, metal silicide, metal nitride, or a metal-containing film.

The contact 130 is connected to the filling pattern 122. The contact 130 contacts at least a portion of the filling pattern 122. The ground voltage or negative voltage may be applied to the filling pattern 122 via the contact 130.

The insulating pattern 124 may extend along a side surface of the filling pattern 122. For example, the insulating pattern 124 may include an insulating material, for example, a metal oxide such as silicon oxide, aluminum oxide, tantalum oxide, or hafnium oxide. The insulating pattern 124 may be interposed between the filling pattern 122 and the first substrate 100 so as to electrically isolate the filling pattern 122 and the first substrate 100 from each other.

Referring to FIG. 5, in some embodiments, the filling pattern 122 may extend through the first substrate 100 and the element isolation pattern 110. The insulating pattern 124 may be interposed between the filling pattern 122 and the first substrate 100 and between the filling pattern 122 and the element isolation pattern 110. A boundary between the element isolation pattern 110 and the insulating pattern 124 may not be defined. The insulating pattern 124 may include the same material as the element isolation pattern 110.

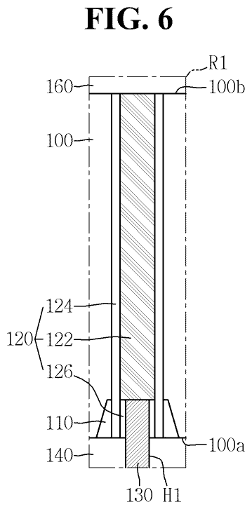

Referring to FIG. 6, in some embodiments, the pixel isolation pattern 120 may further include a capping pattern 126. The filling pattern 122 may be in contact with the second surface 100b of the first substrate 100 and may be spaced apart from the first surface 100a of the first substrate 100. For example, one end of the filling pattern 122 may be in contact with the capping pattern 126 and the contact 130. The capping pattern 126 may be disposed between the filling pattern 122 and the first surface 100a of the first substrate 100. The filling pattern 122 may fill a portion of a trench extending through the first substrate 100, and the capping pattern 126 may fill a portion of the trench on the filling pattern 122. For example, the capping pattern 126 may include at least one of silicon oxide, silicon nitride, and silicon oxynitride. The insulating pattern 124 may extend along a side surface of the filling pattern 122 and a side surface of the capping pattern 126. The capping pattern 126 may be disposed between the contact 130 and the insulating pattern 124. A boundary between element isolation pattern 110 and insulating pattern 124 may not be defined.

The contact 130 may extend through the capping pattern 126 and contact the filling pattern 122.

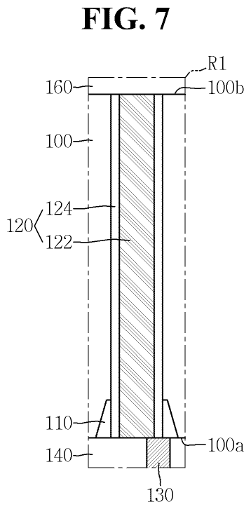

Referring to FIG. 7, the contact 130 may contact a portion of the filling pattern 122. The contact 130 may contact the filling pattern 122 and the insulating pattern 124, or may contact the filling pattern 122, the insulating pattern 124, and the element isolation pattern 110. The contact 130 does not contact the first substrate 100.

In a configuration on an image sensor in which a pad extending from the second surface 100b of the first substrate 100 into the first substrate 100 is formed, a step may be formed between an upper surface of the pad and the second surface 100b. Due to the step, a defective coating process of the color filter 180 and/or a defective patterning process of the micro lens 190 may occur in a process of forming the color filter 180 and/or the micro lens 190 on the second surface 100b.

However, in the image sensor according to aspects of the embodiments disclosed herein, the pad 230 may be disposed within the second structure 20, and the upper surface 230us of the pad 230 may be exposed through the pad opening 230H. Therefore, since no step occurs on the second surface 100b due to the pad 230, the defective coating process of the color filter 180 and/or the defective patterning process of the micro lens 190 may be prevented.

Additionally, in the image sensor according to some embodiments, the filling pattern 122 of the pixel isolation pattern 120 may be electrically connected to the pad 230 via the first wiring structure IS1, the first bonding pad 155, the second bonding pad 255, and the second wiring structure IS2. The filling pattern 122 may be electrically connected to the pad 230 via the contact 130, the first wiring pattern 142 and 144, the first bonding pad 155, the second bonding pad 255, and the second wiring pattern 242, 244, and 280, and thus may receive the ground voltage or negative voltage from the pad 230. This filling pattern 122 may prevent charges generated by ESD (electrostatic discharge) from accumulating on the surface (such as the second surface 100b) of the first substrate 100, and thus may effectively prevent ESD bruise defects. The ESD bruise defect refers to a defect such as a blemish that occurs in an image because charges generated by ESD or the like accumulate on the surface (such as the second surface 100b) of the first substrate 100.

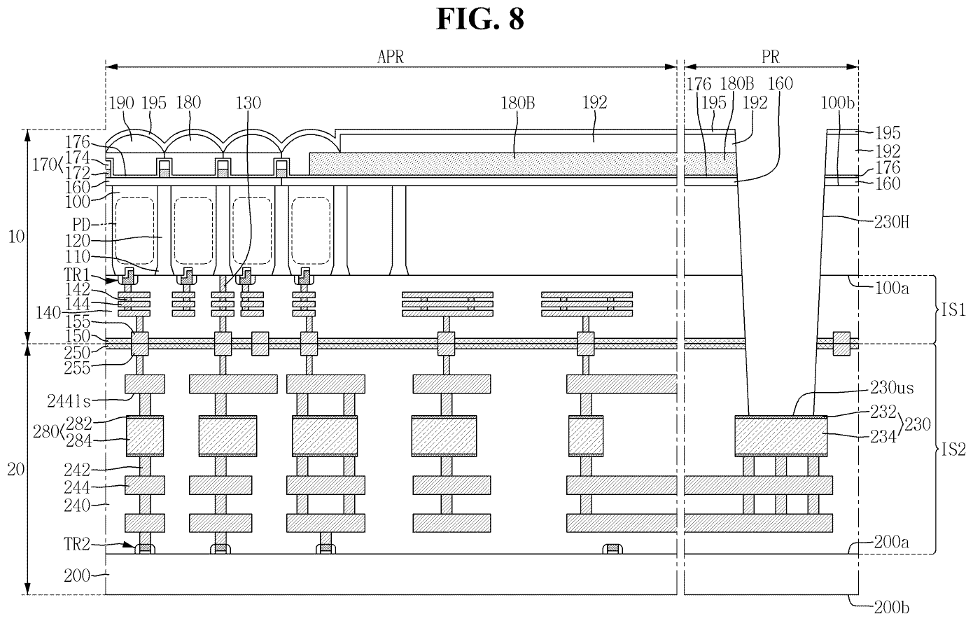

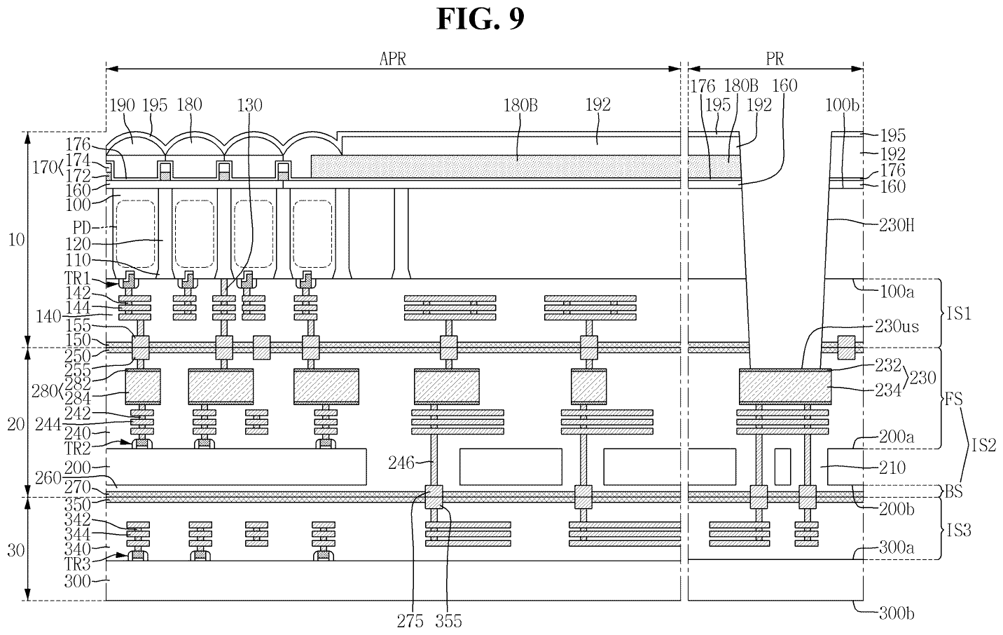

FIG. 8 and FIG. 9 are various schematic cross-sectional views for illustrating an image sensor according to some embodiments. For convenience of description, contents duplicate with those as described above using FIGS. 1 to 7 are briefly described or descriptions thereof are omitted.

Referring to FIG. 8, in the image sensor according to some embodiments, a vertical level of the upper surface 230us of the pad 230 may be lower than a vertical level of a lower surface 244ls of the second wiring line 244 which is closest to the second bonding pad 255 among the second wiring lines 244 and 280. For example, the pad 230 may be formed as a metal layer having a vertical level lower than a vertical level of the second wiring line 244 which is closest to the second bonding pad 255 among the second wiring lines 244 and 280. The pad 230 may be formed as a metal layer having a vertical level lower than a vertical level of the metal layer as shown in FIG. 8.

Referring to FIG. 9, the image sensor according to some embodiments further may include a third structure 30. The second structure 20 may be stacked on the third structure 30. The image sensor may be a stack type image sensor including a stack structure in which the first structure 10, the second structure 20, and the third structure 30 are sequentially stacked.

The third structure 30 may include a third substrate 300, a third circuit element TR3, and a third wiring structure IS3.

The third substrate 300 may be made of bulk silicon or SOI (silicon-on-insulator). The third substrate 300 may be a silicon substrate, or may include a material other than silicon, such as silicon germanium, indium antimonide, lead telluride compound, indium arsenide, indium phosphide, gallium arsenide, or gallium antimonide. Alternatively, the third substrate 300 may have a base substrate and an epitaxial layer formed on the base substrate. For convenience of description, in following embodiments, an example in which the third substrate 300 is embodied as a silicon substrate is described.

The third substrate 300 may include a fifth surface 300a and a sixth surface 300b opposite to each other in a vertical direction. In the following embodiments, the fifth surface 300a may be referred to as a front surface of the third substrate 300, and the sixth surface 300b may be referred to as a back surface of the third substrate 300. In some embodiments, the fifth surface 300a of the third substrate 300 may face the fourth surface 200b of the second substrate 200.

The third circuit element TR3 may be formed on the fifth surface 300a of the third substrate 300. The third circuit element TR3 may be electrically connected to the active pixel area APR and may transmit and receive the electrical signal to and from each unit pixel PX. For example, the third circuit element TR3 may include circuit elements that constitute the row decoder 2, the row driver 3, the column decoder 4, the timing generator 5, the correlated double sampler 6, the analog-to-digital converter 7, or the input/output buffer 8 as described above with reference to FIG. 1.

The third wiring structure IS3 may be formed on the fifth surface 300a of the third substrate 300. The third wiring structure IS3 may include a third inter-wiring insulating film 340 on the fifth surface 300a, a third wiring pattern 342 and 344 within the third inter-wiring insulating film 340, a fourth bonding insulating film 350 on the third inter-wiring insulating film 340, and a fourth bonding pad 355 within the fourth bonding insulating film 350 and/or the third inter-wiring insulating film 340. The third wiring pattern 342 and 344 may include a plurality of third wiring lines 344 and a plurality of third vias 342 connecting the plurality of third wiring lines 344 to each other. The plurality of third vias 342 may connect the fourth bonding pad 355 and the plurality of third wiring lines 344 to each other. The third wiring structure IS3 may be electrically connected to the third circuit element TR3.

In FIG. 9, the number and arrangement of the third wiring patterns 342 and 344 and the position of the fourth bonding pad 355 are merely examples and may vary. The third inter-wiring insulating film 340 may be formed in a stack structure in which a plurality of insulating layers are stacked.

For example, the third inter-wiring insulating film 340 may include silicon oxide, and the fourth bonding insulating film 350 may include silicon oxide, silicon nitride, silicon oxynitride, or silicon carbon nitride. For example, the third wiring pattern 342 and 344 may include at least one of copper (Cu), aluminum (Al), tungsten (W), titanium (Ti), titanium nitride (TiN), tantalum (Ta), tantalum nitride (TaN), ruthenium (Ru), and tungsten nitride (WN).

In some embodiments, the second wiring structure IS2 may include a front wiring structure FS formed on the third surface 200a of the second substrate 200 and including the pad 230, and a back wiring structure BS formed on the fourth surface 200b of the second substrate 200.

The front wiring structure FS may include the second front side inter-wiring insulating film 240 on the third surface 200a, the second wiring patterns 242, 244, 280 and the pad 230 within the second front side inter-wiring insulating film 240, the second bonding insulating film 250 on the second front side inter-wiring insulating film 240, and the second bonding pad 255 within the second bonding insulating film 250 and/or the second front side inter-wiring insulating film 240 as described above using FIGS. 1 to 7.

The back wiring structure BS may include a second back side inter-wiring insulating film 260 on the fourth surface 200b, a third bonding insulating film 270 on the second back side inter-wiring insulating film 260, and a third bonding pad 275 within the third bonding insulating films 270 and/or the second back side inter-wiring insulating film 260.

In FIG. 9, the number of layers and the arrangement of the third bonding pads 275 and the position of the second bonding pad 255 are merely examples and may vary. The second back side inter-wiring insulating film 260 may be formed in a stack structure in which a plurality of insulating layers are stacked.

The second substrate 200 may include a substrate insulating pattern 210 extending through the second substrate 200. A through-electrode 246 may be formed within the substrate insulating pattern 210. The through-electrode 246 may extend through the second front side inter-wiring insulating film 240, the substrate insulating pattern 210, and the second back side inter-wiring insulating film 260 so as to connect the second wiring pattern 242, 244, and 280 and the third bonding pad 275 to each other, and to connect the pad 230 and the third bonding pad 275 to each other. The second wiring structure IS2 may be electrically connected to the third wiring structure IS3 via the through-electrode 246. For example, the substrate insulating pattern 210 may include at least one of silicon oxide and silicon nitride. The through-electrode 246 may include a conductive material.

The second circuit element TR2 may be formed on at least one of the third surface 200a and the fourth surface 200b of the second substrate 200. In some embodiments, the second circuit element TR2 may include circuit elements constituting the pixel PX. The second circuit element TR2 may include various transistors for processing the electrical signal generated from each of the unit pixels PX within the first substrate 100. For example, each of the first circuit element TR1 and the second circuit element TR2 may include the transfer transistor TX, reset transistor RX, the drive transistor DX, or the select transistor SX as described above with reference to FIG. 2.

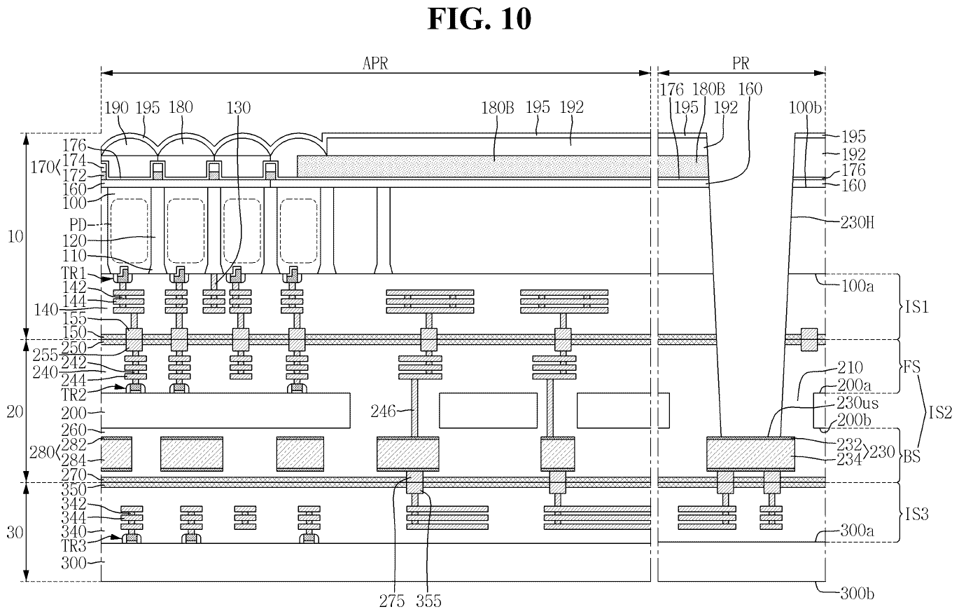

The second structure 20 and the third structure 30 may be bonded to each other. The second wiring structure IS2 and the third wiring structure IS3 may be bonded to each other. For example, as shown in FIG. 10, a lower surface of the second wiring structure IS2 may be attached to an upper surface of the third wiring structure IS3. The second wiring structure IS2 and the third wiring structure IS3 may be bonded to each other in, for example, a wafer bonding process. However, embodiments of the present disclosure are not limited thereto.

The third bonding pad 275 formed as the lowermost metal layer of the second wiring structure IS2 and the fourth bonding pad 355 formed as the uppermost metal layer of the third wiring structure IS3 may contact each other and be attached to each other. For example, the third bonding pad 275 and the fourth bonding pad 355 may be made of copper (Cu), and the third bonding pad 275 and the fourth bonding pad 355 may be bonded to each other in a Cu—Cu bonding manner. In another example, each of the third bonding pad 275 and the fourth bonding pad 355 may be made of various other metals such as aluminum (Al) or tungsten (W). The third bonding pad 275 and the fourth bonding pad 355 may be bonded to each other such that the second wiring structure IS2 and the third wiring structure IS3 may be electrically connected to each other.

The third bonding insulating film 270 and the fourth bonding insulating film 350 may also contact each other and be attached to each other. For example, the second wiring structure IS2 and the third wiring structure IS3 may be stacked in a metal-oxide hybrid bonding manner.

In some embodiments, the pixel isolation pattern 120 may be electrically connected to the pad 230 via the first wiring structure IS1 and the front wiring structure FS, and/or the through-electrode 246, the back wiring structure BS, and the third wiring structure IS3.

FIG. 10 is a schematic cross-sectional view for illustrating an image sensor according to some embodiments. For convenience of description, contents duplicate with those as described above using FIG. 9 are briefly described or descriptions thereof are omitted.

Referring to FIG. 10, in the image sensor according to some embodiments, the second wiring structure IS2 may include the front wiring structure FS formed on the third surface 200a of the second substrate 200, and the back wiring structure BS formed on the fourth surface 200b of the second substrate 200 and including the pad 230.

The back wiring structure BS may include the pad 230, the second wiring pattern 280, and the third bonding pad 275. The front wiring structure FS may include the second wiring pattern 242 and 244 and the second bonding pad 255.

The through-electrode 246 may extend through the second front side inter-wiring insulating film 240, the substrate insulating pattern 210, and the second back side inter-wiring insulating film 260 so as to connect the second wiring pattern 242 and 244 of the front wiring structure FS and the second wiring pattern 280 of the back wiring structure BS to each other. The second wiring pattern 280 may be connected to the fourth bonding pad 355.

The pad opening 230H may extend through the first structure 10 and the front wiring structure FS of the pad area PR. At least a portion of the upper surface 230us of the pad 230 may be exposed through the pad opening 230H.

In some embodiments, the pixel isolation pattern 120 may be electrically connected to the pad 230 via the first wiring structure IS1, the front wiring structure FS, the through-electrode 246, the back wiring structure BS, and/or the third wiring structure IS3.

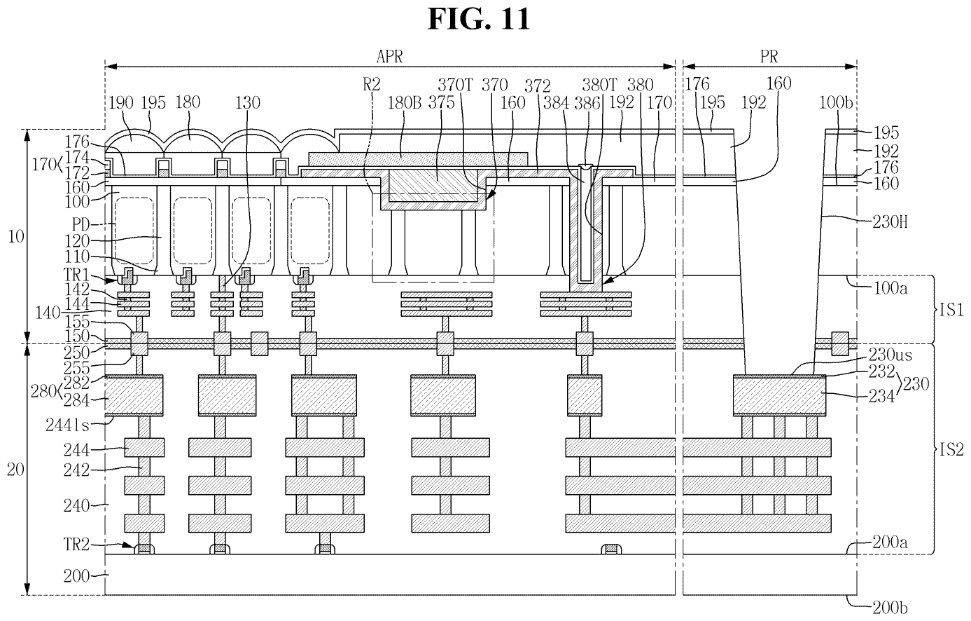

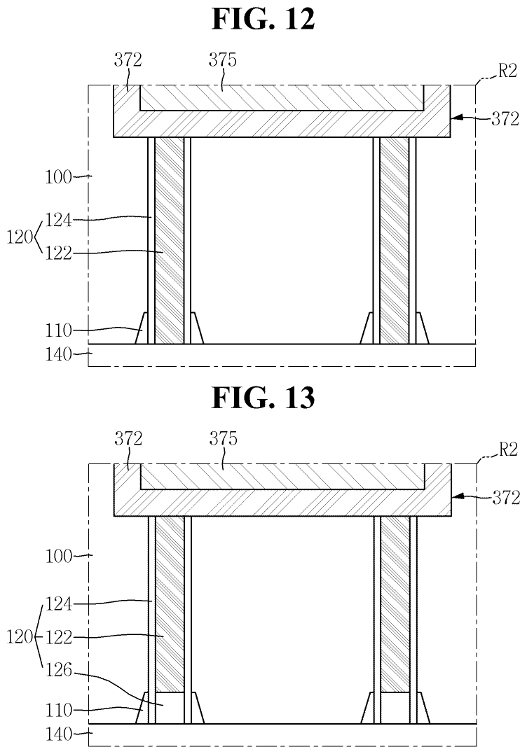

FIG. 11 is a schematic cross-sectional view for illustrating an image sensor according to some embodiments. FIG. 12 and FIG. 13 are various enlarged views of a R2 area in FIG. 11. For convenience of description, contents duplicate with those as described above using FIGS. 1 to 7 are briefly described or descriptions thereof are omitted.

Referring to FIG. 11, in the image sensor according to some embodiments, the first structure 10 may include a first connection via 370 and a second connection via 380. For example, the first connection via 370 and the second connection via 380 may be formed in the first structure 10 of the active pixel area APR. The light-blocking pattern 180B may cover the first connection via 370. In certain embodiments, although not illustrated, the light-blocking pattern 180B may also cover the second connection via 380.

A first conductive pattern 372 and a second conductive pattern 375 within a first trench 370T may constitute the first connection via 370. The first conductive pattern 372 within a second trench 380T may constitute the second connection via 380.

The first conductive pattern 372 may be formed in the first structure 10 of the active pixel area APR. The first conductive pattern 372 may be formed on the surface insulating film 160. The first conductive pattern 372 may connect the pixel isolation pattern 120 and the first wiring structure IS1 to each other. The first conductive pattern 372 may extend from the second surface 100b of the first substrate 100 into the first substrate 100 so as to be connected to the pixel isolation pattern 120.

For example, the first trench 370T, exposing the pixel isolation pattern 120, may be formed within the first substrate 100 and the surface insulating film 160 of the active pixel area APR. The first conductive pattern 372 may be formed within the first trench 370T and may contact the pixel isolation pattern 120. Additionally, the second trench 380T exposing the first wiring line 144 of the active pixel area APR may be formed. The second connection via 380 may be formed within the second trench 380T and may contact the first wiring line 144. The first conductive pattern 372 may extend along a portion of the surface insulating film 160 between the first trench 370T and the second trench 380T. For example, the first conductive pattern 372 may extend conformally along a profile of side and bottom surfaces of each of the first trench 370T and the second trench 380T.

The first conductive pattern 372 may include at least one of, for example, titanium (Ti), titanium nitride (TiN), tantalum (Ta), tantalum nitride (TaN), tungsten (W), aluminum (Al), copper (Cu), and combinations thereof. However, embodiment of the present disclosure are not limited thereto. The second conductive pattern 375 may fill the first trench 370T while being disposed on the first conductive pattern 372. The second conductive pattern 375 may include, but is not limited to, at least one of, for example, tungsten (W), copper (Cu), aluminum (Al), gold (Au), silver (Ag), and alloys thereof.

In some embodiments, the pixel isolation pattern 120 may be electrically connected to the pad 230 via the first connection via 370, the second connection via 380, the first wiring structure IS1, and the second wiring structure IS2, and may receive a ground voltage or a negative voltage from the pad 230. The pixel isolation pattern 120 may be electrically connected to the pad 230 via the first connection via 370, the second connection via 380, the first wiring pattern 142 and 144, the first bonding pad 155, the second bonding pad 255 and the second wiring pattern 242, 244, and 280. For example, the second connection via 380 may be disposed between the first connection via 370 and the pad 230.

In an embodiment, although not illustrated, the first connection via 370 and the second connection via 380 may be formed in the first structure 10 of the pad area PR. That is, the first connection via 370, the second connection via 380, and the pad 230 may be formed around the active pixel area APR in a plan view.

Referring to FIG. 12 and FIG. 13, in some embodiments, the pixel isolation pattern 120 may include a filling pattern 122 and an insulating pattern 124. At least a portion of the filling pattern 122 may be exposed through the first trench (370T in FIG. 11). The filling pattern 122 exposed through the first trench (370T in FIG. 11) may contact the first conductive pattern 372. The ground voltage or negative voltage may be applied to the filling pattern 122 via the first conductive pattern 372 of the first connection via 370.

Referring to FIG. 12, the pixel isolation pattern 120 may include the filling pattern 122 and insulating pattern 124 as described above using FIG. 5.

Referring to FIG. 13, the pixel isolation pattern 120 may include the filling pattern 122, insulating pattern 124, and the capping pattern 126 as similarly described above using FIG. 6. As illustrated in the FIG. 13, contact 130 may not extend through the capping pattern 126 and contact the filling pattern 122. The capping pattern 126 may be disposed between the filling pattern 122 and the first surface 100a of the first substrate 100. The capping pattern 126 may contact the filling pattern 122, the first surface 100a of the first substrate 100, and the insulating pattern 124.

Referring again to FIG. 11, as described above using FIG. 4, in some embodiments, a vertical level of the upper surface 230us of the pad 230 may be higher than the lower surface 244ls of the second wiring line 280 closest to the second bonding pad 255 among the second wiring lines 244 and 280.

In some embodiments, the first protective film 176 may cover the first connection via 370 and the second connection via 380. For example, the first protective film 176 may conformally extend along a profile of each of the first conductive pattern 372, the second conductive pattern 375 and the second connection via 380,

In some embodiments, a filling insulating film 384 may be formed on the first conductive pattern 372 so as to fill the second trench 380T. The filling insulating film 384 may include, but is not limited to, at least one of silicon oxide, aluminum oxide, tantalum oxide, and combinations thereof.

In some embodiments, a capping film 386 may be formed on the filling insulating film 384. The capping film 386 may cover an upper surface of filling insulating film 384.

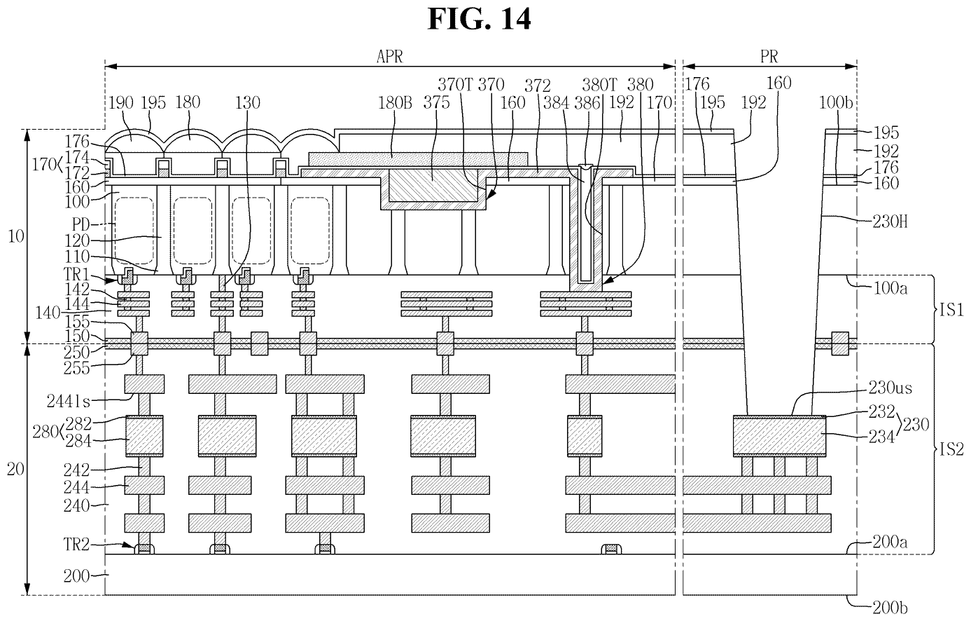

FIGS. 14 to 16 are various schematic cross-sectional views for illustrating an image sensor according to some embodiments. For convenience of description, contents duplicate with those described above using FIGS. 1 to 13 are briefly described or descriptions thereof area omitted.

Referring to FIG. 14, in the image sensor according to some embodiments, as described above using FIG. 8, a vertical level of the upper surface 230us of the pad 230 may be lower than a vertical level of the lower surface 244ls of the second wiring line 244 closest to the second bonding pad 255 among the second wiring lines 244 and 280.

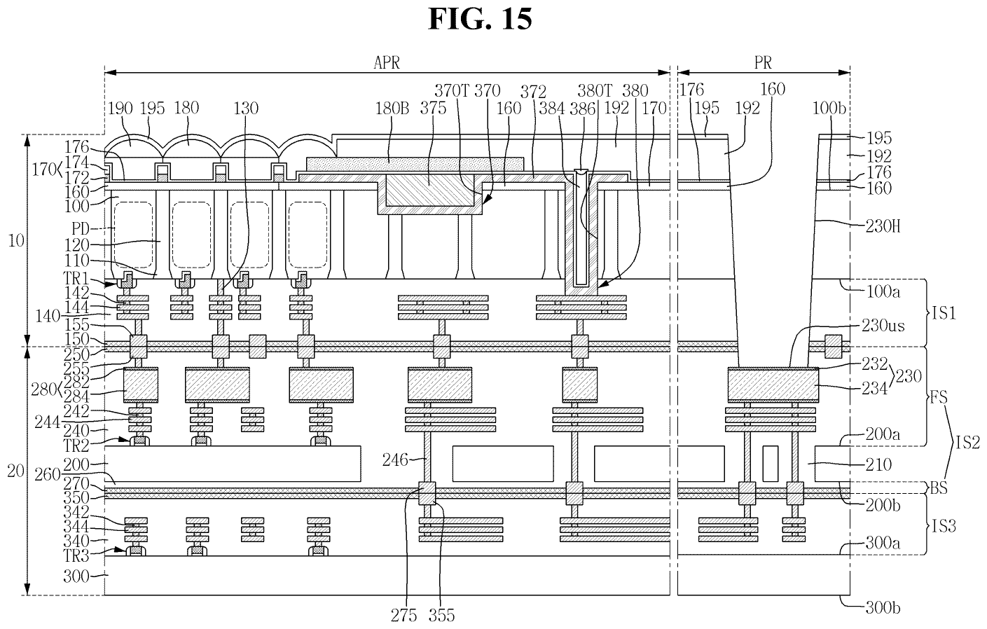

Referring to FIG. 15, the image sensor according to some embodiments may further include the third structure 30 as described above using FIG. 9, and the pad 230 may be formed within the front wiring structure FS.

The pixel isolation pattern 120 may be electrically connected to the pad 230 via the first connection via 370, the second connection via 380, the first wiring structure IS1 and the front wiring structure FS, and/or through-electrode 246, the back wiring structure BS and the third wiring structure IS3.

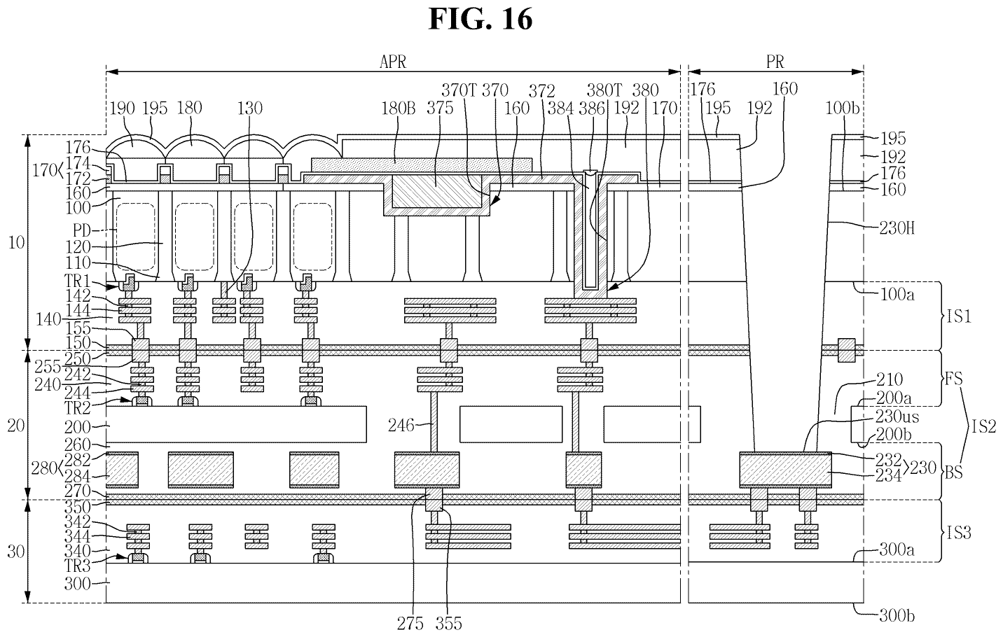

Referring to FIG. 16, the image sensor according to some embodiments may further include the third structure 30 as described above using FIG. 10, and the pad 230 may be formed within the back wiring structure BS.

The pixel isolation pattern 120 may be electrically connected to the pad 230 via the first connection via 370, the second connection via 380, the first wiring structure IS1, the front wiring structure FS, the through-electrode 246, and the back wiring structure BS, and/or the third wiring structure IS3.

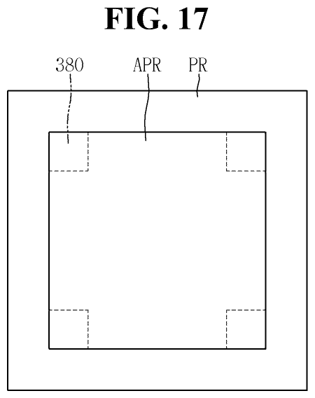

FIG. 17 is an example layout diagram for illustrating an image sensor according to some embodiments. For convenience of description, contents duplicate with those described above using FIGS. 1 to 16 are briefly described or descriptions thereof are omitted.

Referring to FIG. 17, in the image sensor according to some embodiments, the second connection via 380 may be disposed adjacent to the pad 230. The second connection via 380 may be disposed adjacent to a vertex of the active pixel area APR in a plan view. For example, in a plan view, the active pixel area APR may have a rectangular shape and the second connection via 380 may be disposed adjacent to the vertex of the rectangular shape.

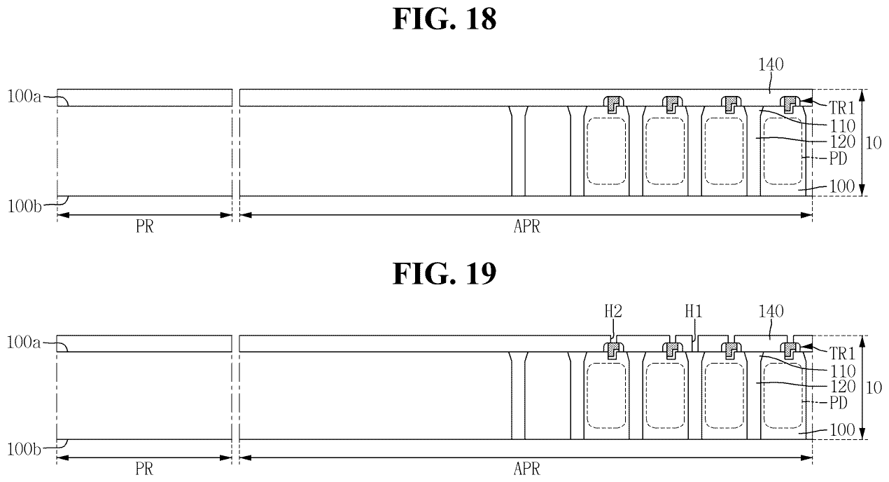

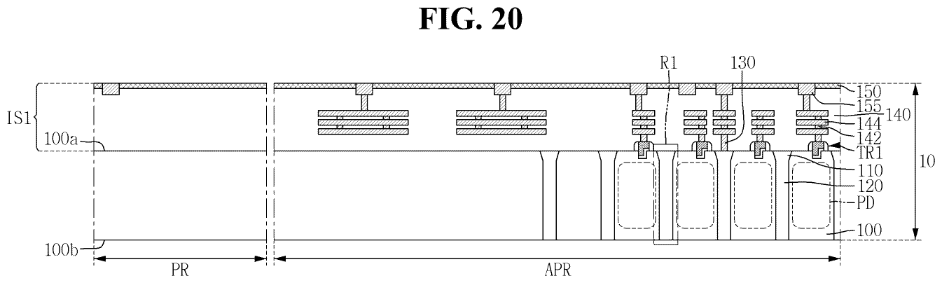

FIGS. 18 to 20 are diagrams of intermediate structures corresponding to intermediate steps of a method for manufacturing an image sensor according to some embodiments. FIGS. 5 to 7 are various enlarged views for illustrating a R1 area in FIG. 20. For convenience of description, contents duplicate with those as described above using FIGS. 1 to 7 are briefly described or descriptions thereof are omitted.

Referring to FIG. 18, the photoelectric conversion area PD, the element isolation pattern 110, and the pixel isolation pattern 120 may be formed within the first substrate 100.

The first substrate 100 may include the first surface 100a and the second surface 100b which are opposite to each other.

The photoelectric conversion area PD may be formed within the first substrate 100. For example, the photoelectric conversion area PD may be formed by ion implanting n-type impurities into the first substrate 100 which is of a p-type. The element isolation pattern 110 may be formed by filling the insulating material in the shallow trench formed by patterning the first surface 100a of the substrate 100.

As shown in FIG. 5, the pixel isolation pattern 120 may be formed by filling the filling pattern 122 and the insulating pattern 124 in a deep trench formed by patterning the first surface 100a of the substrate 100. As shown in FIG. 6, the pixel isolation pattern 120 may be formed by filling the filling pattern 122, the insulating pattern 124, and the capping pattern 126 in a deep trench formed by patterning the first surface 100a of the substrate 100.

For example, the trench may be formed from the first surface 100a of the first substrate 100 into the first substrate 100, the insulating pattern 124 may be formed along a profile of the trench, the filling pattern 122 may be formed on the insulating pattern 124 so as to fill the trench, and a grinding process may be performed on the second surface 100b of the first substrate 100. Accordingly, the insulating pattern 124 and the filling pattern 122 may be not covered with the second surface 100b of the first substrate 100 so as to be exposed.

Subsequently, the first circuit element TR1 may be formed on the first surface 100a of the first substrate 100.

Subsequently, the first inter-wiring insulating film 140 may be formed on the first surface 100a of the first substrate 100. The first inter-wiring insulating film 140 may cover the first surface 100a of the first substrate 100 and the first circuit element TR1.

Referring to FIG. 19, the first hole H1 and the second hole H2 may be formed in the first inter-wiring insulating film 140. The first hole H1 may expose the pixel isolation pattern 120. The second hole H2 may expose the first circuit element TR1, for example.

Referring to FIG. 20, the first wiring structure IS1 may be formed on the first surface 100a of the first substrate 100. The first wiring structure IS1 may include the first inter-wiring insulating film 140, the contact 130, the first vias 142 and the first wiring lines 144 in the first inter-wiring insulating film 140, the first bonding insulating film 150, and the first bonding pad 155 within the first bonding insulating film 150 and/or the first inter-wiring insulating film 140. The first vias 142 may fill the second hole (H2 in FIG. 19).

Referring to FIG. 5, FIG. 7, and FIG. 20, the first hole H1 may extend through the first inter-wiring insulating film 140 so as to expose a portion of the filling pattern 122. The contact 130 may fill the first hole H1.

Referring to FIG. 6 and FIG. 20, the first hole H1 may extend through the first inter-wiring insulating film 140 and the capping pattern 126 so as to expose a portion of the filling pattern 122. The contact 130 may fill the first hole H1.

Next, referring to FIG. 4, the second structure 20 may be bonded to the first wiring structure IS1.

Subsequently, the surface insulating film 160, the grid pattern 170, the first protective film 176, the color filter 180, the light-blocking pattern 180B, the micro lens 190, the planarization film 192 and the second protective film 195 may be formed on the second surface 100b of the first substrate 100. Accordingly, the first structure 10 may be formed.

Subsequently, the pad opening 230H that exposes the upper surface 230us of the pad 230 may be formed. In this way, the image sensor as described above using FIGS. 1 to 7 may be formed.

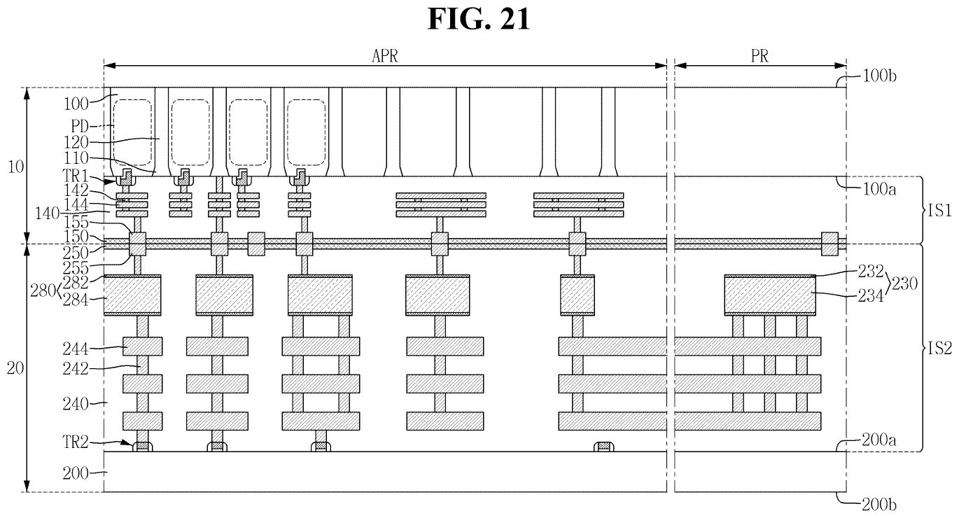

FIGS. 21 to 25 are diagrams of intermediate structures corresponding to intermediate steps of a method for manufacturing an image sensor according to some embodiments. For convenience of description, contents duplicate with those as described above using FIGS. 11 to 13 are briefly described or descriptions thereof are omitted.

Referring to FIG. 21, the element isolation pattern 110 and the pixel isolation pattern 120 may be formed within the first substrate 100. The first circuit element TR1 and the first wiring structure IS1 may be formed on the first surface 100a of the first substrate 100. The second circuit element TR2 and the second wiring structure IS2 may be formed on the third surface 200a of the second substrate 200.

Subsequently, the second structure 20 may be bonded to the first wiring structure IS1 formed on the first surface 100a of the first substrate 100.

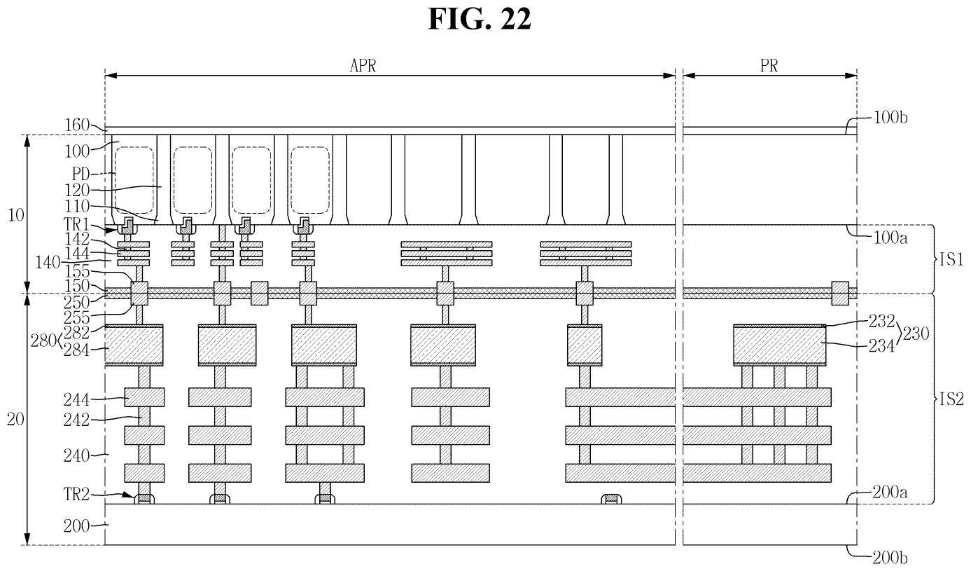

Referring to FIG. 22, the surface insulating film 160 may be formed on the first surface 100a of the first substrate 100.

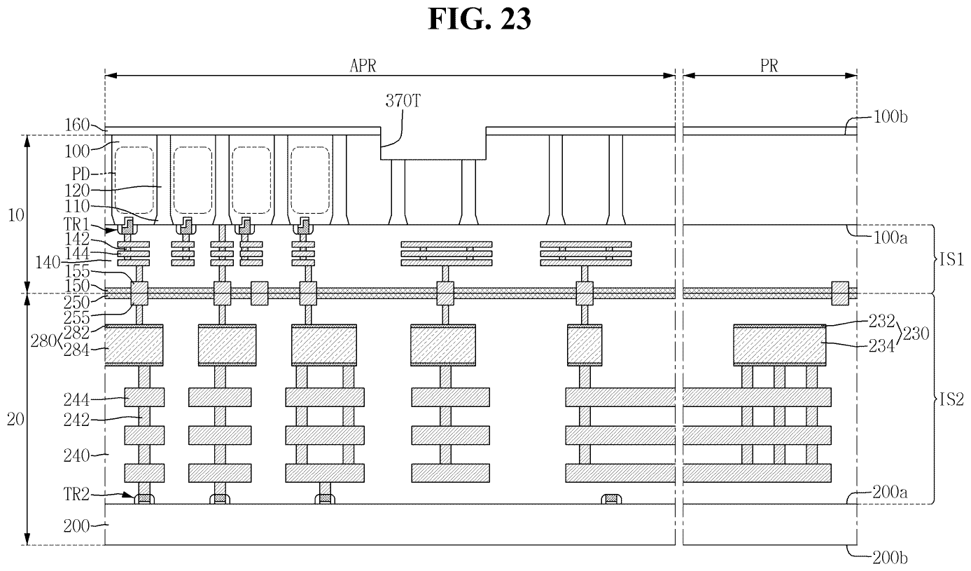

Referring to FIG. 23, the first trench 370T may be formed within the first structure 10 of the active pixel area APR. The first trench 370T may extend through the surface insulating film 160 and a portion of the first substrate 100. The first trench 370T may expose the pixel isolation pattern 120.

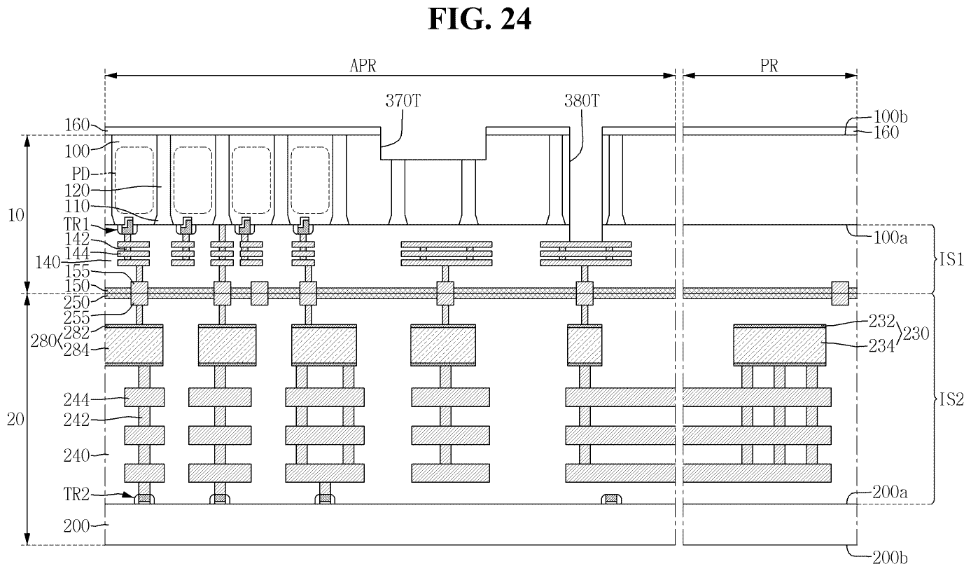

Referring to FIG. 24, the second trench 380T may be formed within the first structure 10 of the active pixel area APR. The second trench 380T may extend through the substrate 100 and the first inter-wiring insulating film 140 so as to expose the first wiring pattern 142 and 144.

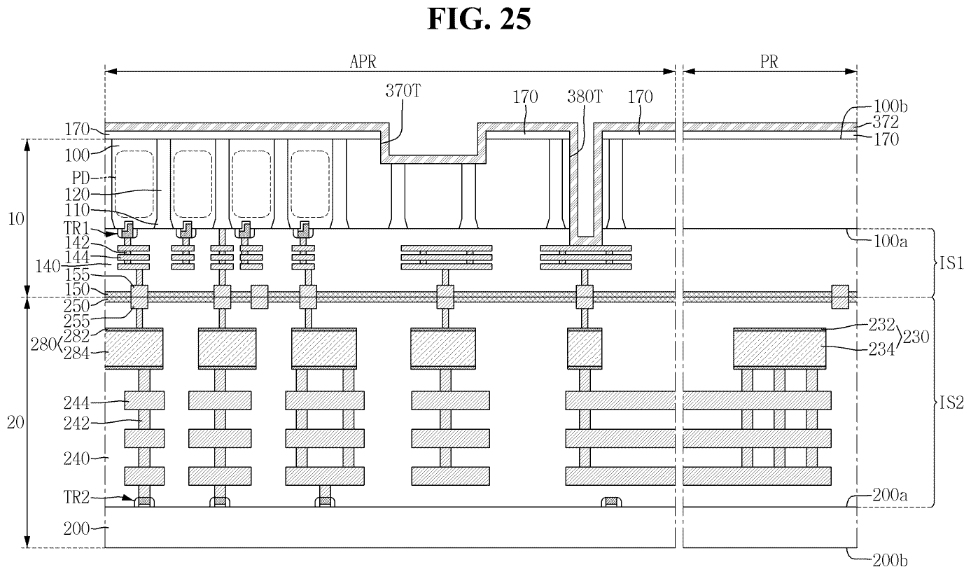

Referring to FIG. 25, the first conductive pattern 372 may be formed on the second surface 100b of the first substrate 100. The first conductive pattern 372 may extend along the surface insulating film 160, the first trench 370T and the second trench 380T. Accordingly, the first conductive pattern 372 may contact the pixel isolation pattern 120 exposed through the first trench 370T, and may contact the first wiring pattern 142 and 144 exposed through the second trench 380T.

Referring to FIG. 11, the first conductive pattern 372 may be patterned. Accordingly, the first conductive pattern 372 of the first connection via 370 and the second connection via 380 may be formed. The second conductive pattern 375 filling the first trench 370T may be formed on the first conductive pattern 372. Accordingly, the first connection via 370 may be formed.

Referring to FIGS. 11 to 13, the first conductive pattern 372 may be in contact with the filling pattern 122.

The grid pattern 170, the first protective film 176, the color filter 180, the light-blocking pattern 180B, the micro lens 190, the planarization film 192, and the second protective film 195 may be formed. Accordingly, the first structure 10 may be formed.

Subsequently, the pad opening 230H that exposes the upper surface 230us of the pad 230 may be formed. In this way, the image sensor as described above using FIGS. 11 to 13 may be formed.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. An image sensor comprising:
a first substrate including a first surface and a second surface opposite to each other;
a first trench disposed on an active pixel area in the first substrate;
a first wiring structure disposed on the first surface of the first substrate, the first wiring structure includes a first wiring pattern and a first bonding pad electrically connected to the first wiring pattern;
a second substrate; and
a second wiring structure disposed on the second substrate, the second wiring structure includes a second wiring pattern, a pad, and a second bonding pad electrically connected to the pad and the second wiring pattern,
wherein the first bonding pad is in contact with the second bonding pad,
wherein at least a portion of the pad is configured to connect to a pad opening extending through the first substrate,
wherein the first trench is configured to electrically connect to the pad via the first wiring pattern, the first bonding pad, the second bonding pad, and the second wiring pattern, and
wherein the active pixel area comprises a light receiving area, a light-blocking area, and an area disposed between the light-blocking area and a pad area.

2. The image sensor of claim 1, wherein the first wiring structure includes a contact contacting at least a portion of the first trench and vertically overlapping with first trench.

3. The image sensor of claim 2, wherein the first trench is in contact with the first surface of the first substrate.

4. The image sensor of claim 3, wherein the first trench is configured to receive a negative bias voltage.

5. The image sensor of claim 4, wherein the first trench is disposed on the active pixel area.

6. The image sensor of claim 4, wherein the first trench is disposed on the light-blocking area.

7. The image sensor of claim 4, wherein the first trench is disposed on the area between the light-blocking area and the pad area.

8. The image sensor of claim 5, further comprising:
a first circuit element on the first surface of the first substrate,
wherein the first trench is configured to separates a first photoelectric conversion area and a second photoelectric conversion area,
wherein the first circuit element is electrically connected to the first photoelectric conversion area, and
wherein a portion of the first circuit element extends into the first substrate.

9. The image sensor of claim 6, further comprising:
a second trench configured to separate a first photoelectric conversion area and a second photoelectric conversion area,
wherein the first trench has a first height in a direction perpendicular to the first surface of the first substrate and the second trench has a second height in the direction, and
wherein the first height is different from the second height.

10. The image sensor of claim 9, wherein the first height is shorter than the second height.

11. The image sensor of claim 3, wherein the contact extends into the first substrate.

12. An image sensor comprising:
a first substrate including a first surface and a second surface opposite to each other;
a first wiring structure on the first surface of the first substrate, the first wiring structure comprises a first bonding pad;
a first trench in the first substrate and in contact with the first surface of the first substrate;
a second substrate; and
a second wiring structure disposed on the second substrate, the second wiring structure comprises a second bonding pad and a pad,
wherein the pad is configured to electrically connect to the first trench through the second bonding pad and the first bonding pad, and
wherein at least a portion of the pad is connected to a pad opening extending through the first substrate.

13. The image sensor of claim 12, wherein the second wiring structure further comprising:
a first via connected to the pad; and
a first wiring pattern connected to the first via,
wherein the pad is configured to electrically connect to the first trench through the first via, the first wiring pattern, the second bonding pad, and the first bonding pad, and
wherein a distance from the first wiring pattern to the first surface of the first substrate is greater than a distance from the second bonding pad to the first surface of the first substrate.

14. The image sensor of claim 13, wherein the first trench is configured to receive a negative bias voltage.

15. The image sensor of claim 14, further comprising:
a second trench in the first substrate,
wherein the pad is configured to electrically connect to the second trench through the first via and the first wiring pattern.

16. The image sensor of claim 13, wherein the first trench is configured to separate a first photoelectric conversion area and a second photoelectric conversion area.

17. The image sensor of claim 13, wherein the first trench is disposed on a light-blocking area.

18. The image sensor of claim 16, wherein the first wiring structure includes a contact contacting at least a portion of the first trench and vertically overlapping with first trench.

19. An image sensor comprising:
a first substrate including a first surface and a second surface opposite to each other;
a first wiring structure on the first surface of the first substrate, the first wiring structure comprises a first bonding pad;
a first trench in the first substrate in contact with the first surface of the first substrate and the second surface of the first substrate;
a second substrate; and
a second wiring structure disposed on the second substrate, the second wiring structure comprises a second bonding pad and a pad,
wherein the pad is configured to electrically connect to the first trench through the second bonding pad and the first bonding pad,
wherein at least a portion of the pad connected to a pad opening extending via the first substrate, and
wherein the first trench comprises a filling pattern, an insulating pattern disposed between the filling pattern and the first substrate, and a capping pattern disposed in the first substrate and in contact with the filling pattern.

20. The image sensor of claim 19, wherein the second wiring structure further comprising:
a first via connected to the pad; and
a first wiring pattern connected to the first via,
wherein the pad is configured to electrically connect to the first trench through the first via, the first wiring pattern, the second bonding pad, and the first bonding pad, and
wherein a distance from the first wiring pattern to the first surface of the first substrate is greater than a distance from the second bonding pad to the first surface of the first substrate.
